(19) United States
(12) Patent Application Publication
(10) Pub. No.: US 2004/0085019 A1
(43) Pub. Date: May 6, 2004

(54) Organic light-emitting diode

(76) Inventors: Ling-Ta Su, Chiai (TW); Shea-Jue Wang, Taipei (TW); Mao-Kuo Wei, Banchiau City (TW)

Correspondence Address: BIRCH STEWART KOLASCH & BIRCH, PO BOX 747, FALLS CHURCH, VA, 22040-0747, US

(21) Appl. No.: 10/691,204

(22) Filed: Oct. 23, 2003

(30) Foreign Application Priority Data
Oct. 25, 2002 (TW) 091217194

(51) Int. Cl. H05B 33/00

(52) U.S. Cl. 313/506

(57) ABSTRACT

An organic light-emitting diode (OLED) comprises a transparent substrate, a first electrode, at least one organic functional layer, a second electrode, and a lid. The first electrode is disposed on the transparent substrate, the organic functional layer is disposed on the first electrode, the second electrode is disposed on the organic functional layer, and the lid is disposed above the second electrode. The lid has at least one heat-dissipating pin mounted on the lid. Furthermore, the lid is composed of a covering component and a heat-dissipating component. The covering component is disposed on or above the second electrode, and the heat-dissipating component is disposed on the covering component.

### BACKGROUND OF THE INVENTION

1. Field of Invention

The invention relates to an organic light-emitting diode (OLED) and, in particular, to an OLED, which has enhanced heat dissipation performance.

2. Related Art

Organic light-emitting diodes (OLEDs) possess the advantages of self-emissive, full viewing angle, high power efficiency, easily manufactured, low cost, rapid response, and full color. Hence, OLEDs are rapidly becoming a major choice for flat panel display technology or flat light source in the future.

Those skilled in the art should know that OLEDs utilize the self-emissive properties of certain organic functional materials to achieve the object of display. OLEDs are divided into small molecule OLEDs (SM-OLEDs) and polymer light-emitting devices (PLEDs) according to the molecular weight of the organic functional materials.

With reference to FIG. 1, an OLED 1 is mainly consisted of a transparent substrate 11, a first electrode 12, an organic functional layer 13, a second electrode 14, and a lid 15. When applying a current to the OLED 1, holes are injected from the first electrode 12 into the organic functional layer 13 while electrons are injected from the second electrode 14. While applying a voltage or a current, the holes and electrons are moved in the organic functional layer 13, and are combined to generate excitons. The excitons can excite materials of the organic functional layer 13, so that the excited materials emit light to release energy.

Additionally, an OLED 2 (shown in FIG. 2) includes a transparent substrate 11, a first electrode 12, an organic functional layer 13, a second electrode 14, and a passivation film 16. The first electrode 12, organic functional layer 13 and second electrode 14 are formed on the transparent substrate 11 sequentially. Finally, the passivation film 16 is formed to encapsulate the first electrode 12, organic functional layer 13 and second electrode 14.

Heat dissipation is one of the most important factors for influencing the emitting efficiency of an OLED. In detail, when applying current to an OLED to emit light, heat is also generated accompanying with the light. For example, in the organic functional layer 13, approximately 25% of the energy is transformed into radiation, while the remaining energy is transformed into heat. Due to this generated heat may accumulate between the transparent substrate 11 and lid 15 or passivation layer 16, so that the heat cannot be dissipated efficiently. The center of a large dimension OLED is particularly prone to heat accumulation.

It is an important characteristic of the OLED to have the organic functional materials, however, these materials cannot stand high temperature. When the temperature of the OLED increases, the emitting efficiency and uniformity of the OLED may suffer due to the heat accumulation between the transparent substrate 11 and lid 15 or passivation layer 16. Moreover, the OLED may be damaged due to the accumulated heat. Therefore, it is necessary to employ a highly efficient heat-dissipating mechanism to increase the lifetime of the OLED.

As mentioned above, the power consumptions of the OLEDs emitting light of different colors are described in the following. An OLED emitting 100 cd/m² of blue light consumes about 10.14 mw/cm² of power while an OLED emitting 500 cd/m² of blue light consumes about 56.27 mw/cm². An OLED emitting 100 cd/m² of green light consumes about 3.48 mw/cm² of power while an OLED emitting 500 cd/m² of green light consumes about 16.03 mw/cm². An OLED emitting 100 cd/m² of yellow light consumes about 4.8 mw/cm² of power while an OLED emitting 500 cd/m² of yellow light consumes about 30.81 mw/cm². As the preceding demonstrates, the power consumption of an OLED increases corresponding to increased brightness, and the temperature of the OLED increases accordingly.

Therefore, it is an important subjective to provide an OLED, which has enhanced heat dissipation performance.

### SUMMARY OF THE INVENTION

In view of the above-mentioned problems, an objective of the invention is to provide an OLED, which has enhanced heat dissipation performance to improve the lifetime thereof.

To achieve the above-mentioned objective, an OLED of the invention comprises a transparent substrate, a first electrode, at least one organic functional layer, a second electrode and a lid. In the invention, the first electrode is disposed on the transparent substrate, the organic functional layer is disposed on the first electrode, and the second electrode is disposed on the organic functional layer. The lid is provided above the second electrode and has at least one heat-dissipating pin mounted on the lid.

Furthermore, the invention also provides an OLED, which comprises a transparent substrate, a first electrode, at least one organic functional layer, a second electrode, a covering component and a heat-dissipating component. In this case, the first electrode, organic functional layer and second electrode are disposed on the transparent substrate sequentially. The covering component is disposed above the second electrode, and the heat-dissipating component is disposed on the covering component. The heat-dissipating component has at least one heat-dissipating pin formed thereon.

Since the OLED of the invention has the heat-dissipating pin to increase the surface area of the lid or the heat-dissipating component, the heat dissipation performance thereof is efficiently enhanced. Moreover, at least a sink can be used to increase the surface area and further enhance heat dissipation performance.

To further increase the heat dissipation performance, a heat conduction method, providing a main body contacting with the heat-dissipating pin, or a forced convection method utilizing a fan, or a thermal radiation method may also be employed.

### BRIEF DESCRIPTION OF THE DRAWINGS

The invention will become more fully understood from the detailed description given hereinbelow illustrations only, and thus is not limitative of the present invention, wherein:

FIG. 1 is a schematic illustration showing a conventional OLED, which includes a lid;

FIG. 2 is a schematic illustration showing another conventional OLED, which includes a passivation film;

FIG. 3 is a schematic illustration showing an OLED according to a preferred embodiment of the invention, wherein the lid and heat-dissipating pins are formed together;

FIG. 4 is a schematic illustration showing an OLED according to another embodiment of the invention, wherein the OLED further includes a fan mounted on a main body;

FIG. 5 is a schematic illustration showing an OLED according to another embodiment of the invention, wherein the heat-dissipating pins are attached to the lid with a heat-conducting adhesive;

FIG. 6 is a schematic illustration showing an OLED according to another embodiment of the invention, wherein the covering component is a lid; and

FIG. 7 is a schematic illustration showing an OLED according to another embodiment of the invention, wherein the covering component is a passivation film.

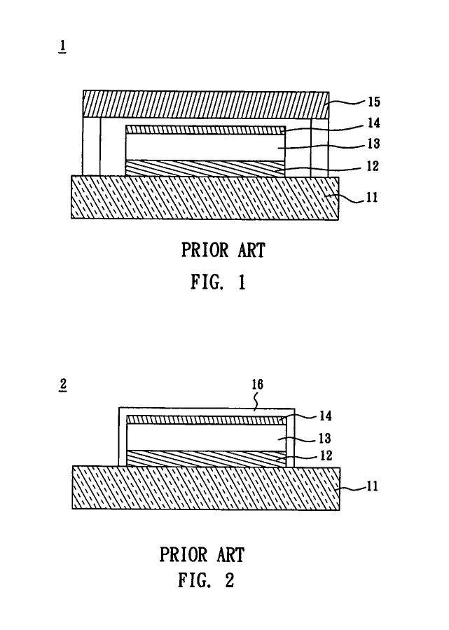

### DETAILED DESCRIPTION OF THE INVENTION

The organic light-emitting diode (OLED) according to preferred embodiments of the invention will be described herein below with reference to the accompanying drawings, wherein the same reference numbers refer to the same elements.

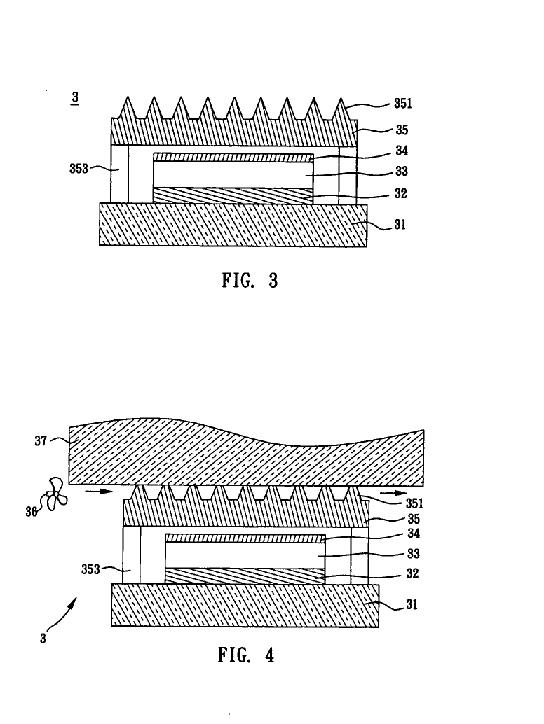

Referring to FIG. 3, an OLED 3 according to a preferred embodiment of the invention comprises a transparent substrate 31, a first electrode 32, an organic functional layer 33, a second electrode 34 and a lid 35.

The first electrode 32 is disposed on the transparent substrate 31, the organic functional layer 33 is disposed on the first electrode 32, and the second electrode 34 is disposed on the organic functional layer 33. The lid 35 is disposed above the second electrode 34, and at least one heat-dissipating pin 351 is mounted on the lid 35. In the current embodiment, a plurality of heat-dissipating pins 351 are mounted on the lid 35 and are arranged in a matrix.

In the current embodiment, the transparent substrate 31 can be a glass, plastic or flexible substrate. In particular, the flexible substrate or plastic substrate can be made of polycarbonate (PC), polyester (PET), cyclic olefin copolymer (COC), metallocene-based cyclic olefin copolymer (mCOC), or thin glass.

The first electrode 32 is disposed on the transparent substrate 31. In the present embodiment, the first electrode 32 is disposed on the transparent substrate 31 by sputtering or ion plating. The first electrode 32 is usually used as an anode and made of a transparent conductive metal oxide, such as indium-fin oxide (ITO), aluminum-zinc oxide (AZO), or indium-zinc oxide (IZO).

The organic functional layer 33 in the current embodiment is disposed on the first electrode 32. The organic functional layer 33 usually contains a hole injection layer, a hole transporting layer, an electroluminescent layer, an electron transporting layer, and an electron injection layer (not shown). For example, the hole injection layer is mainly composed of copper phthalocyanine (CuPc), the hole transporting layer is mainly composed of 4,4′-bis[N-(1-naphthyl)-N-phenylamino]biphenyl (NPB), the electron injection layer is mainly composed of lithium fluoride (LiF), and the electron transporting layer is mainly composed of tris(8-quinolinato-N1,08)-aluminum (Alq). Each layer of the organic functional layer 33 can be disposed upon the first electrode 32 by evaporation, spin coating, ink jet printing, or printing. In addition, the light emitted from the organic functional layer 33 can be blue, green, red, white or other monochromatic light, or color light.

The second electrode 34 is typically used as a cathode and is disposed on the organic functional layer 33 by evaporation or sputtering. The material of the second electrode 34 can be aluminum, calcium, or magnesium-silver alloys. The material of the second electrode 34 can also be aluminum/lithium fluoride, or silver.

A sealing composition 353, such as an adhesive, UV cured glue, or epoxy, is disposed on the transparent substrate 31 and is located at the periphery of the first electrode 32, organic functional layer 33 and second electrode 34. The lid 35 is disposed above the transparent substrate 31 and is supported by the sealing composition 353. Thus, the lid 35, sealing composition 353 and transparent substrate 31 form an airtight space, in which the first electrode 32, organic functional layer 33 and second electrode 34 are located. This may prevent erosion by water or oxygen of the organic functional layer 33. The lid 35 and heat-dissipating pins 351 are formed together, and consist of heat-conducting materials. Put simply, the lid 35 and heat-dissipating pins 351 consist of heat-conducting materials, which have heat-conducting coefficients larger than 50 W/m-k. For example, the heat-conducting material is copper or aluminum. The power dissipation of the lid 35 and heat-dissipating pins 351 is equal to or less than 5° C./W. The radiation coefficient of the color of the lid 35 or the heat-dissipating pins 351, such as black or gray, is greater than 0.9. Thus, the heat dissipation via thermal radiation of the heat-dissipating pins 351 is enhanced. As mentioned above, since the OLED 3 includes lid 35 and heat-dissipating pins 351 for enhancing heat dissipation performance, the operational temperature of the OLED 3 can be maintained below 60° C.

It should be noted that the heat-dissipating pins 351 of this embodiment are conical. The shape of the heat-dissipating pins 351, however, can be any convex shape, which increases the surface area of the heat-dissipating pins 351, such as a cylinder, column, arc convex, and the like. Alternately, a sink or sinks can be provided to increase the surface area to dissipate heat.

With reference to FIG. 4, the OLED 3 may further include a fan 36, which is disposed aside the heat-dissipating pins 351. Furthermore, the OLED 3 is mounted on a main body 37, and the heat-dissipating pins 351 contact the main body 37. In the current embodiment, the fan 36 can be any kind of fan, such as a CPU fan. The main body 37 can be an assembling case or a surface. In this case, since the heat-dissipating pins 351 contact the main body 37, heat can be dissipated via the heat-dissipating pins 351 and main body 37 by heat conduction. Moreover, since the fan 36 may induce the airflow, the convection of the air around the heat-dissipating pins 351 is increased, further enhancing heat dissipation performance.

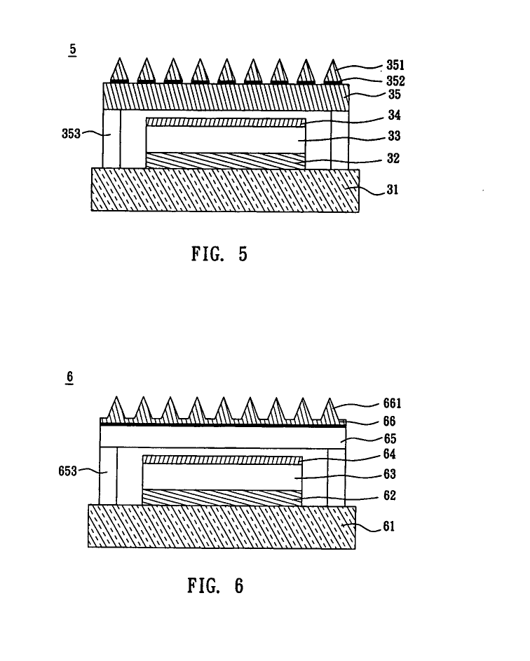

The heat-dissipating pins 351 can be attached to the lid 35 with a heat-conducting adhesive. Referring to FIG. 5, in an OLED 5 according to another embodiment of the invention, the heat-dissipating pins 351 are attached to the lid 35 with the heat-conducting adhesive 352.

With reference to FIG. 6, an OLED 6 according to another embodiment of the invention includes a transparent substrate 61, a first electrode 62, an organic functional layer 63, a second electrode 64, a covering component 65, and a heat-dissipating component 66.

In this embodiment, the transparent substrate 61, first electrode 62, organic functional 63, and second electrode 64 are the same as those previously mentioned. The covering component 65 is the same as the lid 35 and is supported by the sealing composition 653, which is provided at the periphery of the first electrode 62, organic functional layer 63, and second electrode 64. Therefore, the transparent substrate 61, covering component 65, and sealing composition 653 form an airtight space. The first electrode 62, organic functional layer 63 and second electrode 64 are disposed in the airtight space and are isolated to prevent erosion by water and oxygen. The heat-dissipating component 66 is attached to the covering component 65, and an array of heat-dissipating pins 661 is disposed on the heat-dissipating component 66. The heat-dissipating component 66 and heat-dissipating pins 661 are formed together.

As mentioned above, the covering component 65 and/or the heat-dissipating component 66 are made of heat-conducting materials, which have heat-conducting coefficients larger than 50 W/m-k. For example, the heat-conducting material is copper or aluminum. The power dissipation of the heat-dissipating component 66 is equal to or less than 5° C./W. The radiation coefficient of the color of the heat-dissipating component 66, such as black or gray, is greater than 0.9. Thus, the heat dissipation via thermal radiation of the heat-dissipating component 66 is enhanced. Since the OLED 6 includes the heat-dissipating component 66 to enhance heat dissipation performance, the operational temperature of the OLED 6 can be maintained below 60° C.

It should be noted that the heat-dissipating pins 661 of this embodiment are conical. The shape of the heat-dissipating pins 661, however, can be any convex shape, which can increase the surface area of the heat-dissipating pins 661, such as a cylinder, column, arc convex, and the like. Alternately, a sink or sinks can be provided to increase the surface area for dissipating heat. Furthermore, the OLED 6 may be mounted on a main body (not shown) to dissipate heat by way of heat conduction. In addition, the OLED 6 may further include a fan (not shown), which is disposed aside the heat-dissipating pins 661 to increase heat dissipation performance by heat convection.

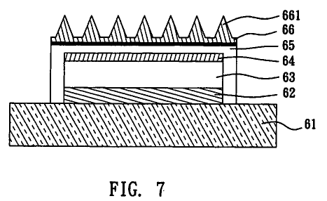

With reference to FIG. 7, the covering component 65 can also be a passivation film, wherein the other elements are the same as those above-mentioned.

In summary, the OLED of the invention employs heat-dissipating pins to increase the surface area to better dissipate heat. Moreover, the heat-dissipating pins contact the main body to increase heat conduction, and a fan is used to increase heat convection. Therefore, the OLED of the invention provides enhanced heat dissipation performance, thus increasing product lifetime.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An organic light-emitting diode (OLED), comprising:
a transparent substrate;
a first electrode disposed on the transparent substrate;
at least one organic functional layer disposed on the first electrode;
a second electrode disposed on the organic functional layer; and
a lid disposed above the second electrode has at least one heat-dissipating pin mounted on the lid.

2. The OLED of claim 1, wherein the lid and the heat-dissipating pin are formed together.

3. The OLED of claim 1, wherein the operational temperature of the OLED is equal to or less than 60° C.

4. The OLED of claim 1, wherein the lid and/or the heat-dissipating pin are made of a heat-conducting material.

5. The OLED of claim 4, wherein the heat-conducting material has a heat-conducting coefficient larger than 50 W/m-k.

6. The OLED of claim 1, wherein the radiation coefficient of the color of the heat-dissipating pin is greater than 0.9.

7. The OLED of claim 1, wherein the OLED is mounted on a main body contacted with the heat-dissipating pin.

8. The OLED of claim 1, wherein the lid and the heat-dissipating pin have power
dissipation equal to or less than 5° C./W.

9. The OLED of claim 1, further comprising:
a fan disposed aside the heat-dissipating pin.

10. An organic light-emitting diode (OLED), comprising:
a transparent substrate;
a first electrode disposed on the transparent substrate;
at least one organic functional layer disposed on the first electrode;
a second electrode disposed on the organic functional layer;
a covering component disposed above the second electrode; and
a heat-dissipating component disposed on the covering component.

11. The OLED of claim 10, wherein the operational temperature of the OLED is equal to or less than 60° C.

12. The OLED of claim 10, wherein the heat-dissipating component has power dissipation equal to or less than 5° C./W.

13. The OLED of claim 10, further comprising:
a fan disposed aside the heat-dissipating component.

14. The OLED of claim 10, wherein the covering component is a lid.

15. The OLED of claim 10, wherein the covering component is a passivation film.

16. The OLED of claim 10, wherein at least one heat-dissipating pin is disposed on the heat-dissipating component.

17. The OLED of claim 10, wherein the covering component and/or the heat-dissipating component are made of a heat-conducting material.

18. The OLED of claim 17, wherein the heat-conducting material has a heat-conducting coefficient larger than 50 W/m-k.

19. The OLED of claim 16, wherein the radiation coefficient of the color of the heat-dissipating pin is greater than 0.9.

20. The OLED of claim 16, wherein the OLED is mounted on a main body contacted with the heat-dissipating pin contacts the main body.
